(19) United States
(12) Patent Application Publication
(10) Pub. No.: US 2023/0327652 A1
(43) Pub. Date: Oct. 12, 2023

(54) SEMICONDUCTOR DEVICE AND INPUT SIGNAL CONTROLLING METHOD

(71) Applicant: RENESAS ELECTRONICS CORPORATION, Tokyo (JP)

(72) Inventor: Wataru ISHIJIMA, Tokyo (JP)

(21) Appl. No.: 17/717,728

(22) Filed: Apr. 11, 2022

(51) Int. Cl. H03K 3/013; H03K 17/16

(52) U.S. Cl. CPC H03K 3/013; H03K 17/16

(57) ABSTRACT

To reduce the deterioration of the input circuit hysteresis characteristics even when the input noise occurs. An input-output circuit of the input terminal side and the output terminal side of the input-output circuit, when the output of the adjacent output terminal is toggled, the output of the input circuit masks the input of the input terminal side of the input circuit so as to hold the previous value.

### BACKGROUND

The present invention relates to a schmitt circuit which can reduce the deterioration of the input circuit hysteresis characteristics when the input and output terminals of a semiconductor device outputs.

For chattering prevention and noise prevention, a schmitt circuit having a hysteresis characteristic (also called hysteresis circuit and schmitt trigger circuit) is often used in the input circuit or the like of the semiconductor device.

As an example of the schmitt circuit, FIG. 10 is a circuit diagram showing an inverter feedback type schmitt circuit. The schmitt circuit 10 is composed of three stages of inverters 101, 102, 103, and each inverter 101, 102, 103 is composed of p-channel MOS transistors 1011, 1021, 1031 and n-channel MOS transistors 1012, 1022, 1032.

In FIG. 10, when the schmitt output signal VSOUT from an output terminal 105 is “Low (L)”, the p-channel MOS transistor 1021 of the second stage inverter 102 is “ON”, the threshold value of the n-channel MOS transistor 1012 of the first stage inverter 101 is shifted above the current drawn by the p-channel MOS transistor 1021.

On the other hand, when the schmitt output signal VSOUT outputted from the output terminal 105 is “High(H)”, the n-channel MOS transistor 1022 of the second stage inverter 102 is turned “ON”, the threshold value of the p-channel MOS transistor 1011 of the first stage inverter 101 is n-channel MOS transistor 1022 shifts below the current drawn.

As described above, the threshold value in case that the schmitt output signal VSOUT is inverted to “High (H)” is different from the threshold value in case that the schmitt output signal VSOUT is inverted to “Low(L)”. This difference is a hysteresis width, by thus having a hysteresis width, since the output of the schmitt circuit at the potential between this is held at a previous value, it is possible to prevent erroneous determination due to input noise.

There are disclosed techniques listed below.
[Patent Document 1] Japanese Unexamined Patent Application Publication No. 2000-349601

Further, Patent Document 1 discloses a schmitt circuit used as an input circuit of CMOS semiconductor integrated circuit device.

### SUMMARY

In the inverter feedback type schmitt circuit in FIG. 10, if the input noise has an amplitude that falls within the hysteresis width, the influence thereof can be prevented.

However, if the input noise of amplitude exceeding the hysteresis amplitude is generated, the schmitt circuit is erroneously reacted and the hysteresis width is narrowed. Further, when the power supply voltage of the schmitt circuit is lowered, the threshold value is also lowered, so that it reacts to noise having a smaller amplitude.

The present invention is to solve the above problems, it is to provide a circuit for reducing the deterioration of the input circuit hysteresis characteristics even when the input noise occurs.

In the semiconductor device according to an embodiment, when an input-output circuit of the input terminal side, the output terminal side of the input-output circuit and an output of the adjacent output terminal are toggled, the input of the input circuit of the input terminal side masked output of the input circuit so as to hold the previous value. Thus, it is possible to reduce the deterioration of the input circuit hysteresis characteristics even when the input noise occurs.

It is possible to reduce the deterioration of the input circuit hysteresis characteristics when the input and output terminals of the semiconductor device outputs.

### BRIEF DESCRIPTION OF THE DRAWINGS

FIG. 1 is a configuration diagram of a semiconductor device according to a first embodiment.

FIG. 2 is a configuration diagram of an input-output unit in the semiconductor device according to the first embodiment.

FIG. 3 is a configuration diagram showing an example of a schmitt circuit in the semiconductor device according to the first embodiment.

FIG. 4 is a waveform diagram of a time transition of the potential of the schmitt input-output signal according to the first embodiment.

FIG. 5 is a waveform diagram of a time transition of the potential of the schmitt input-output signal according to the first embodiment.

FIG. 6 is a waveform diagram of a time transition of the potential of the schmitt input-output signal according to the first embodiment.

FIG. 7 is a configuration diagram showing an example of a schmitt circuit in a semiconductor device according to a second embodiment.

FIG. 8 is a truth table of the RS flip-flop circuit in the schmitt circuit according to the second embodiment.

FIG. 9 is a configuration diagram showing an example of a schmitt circuit in a semiconductor device according to a third embodiment.

FIG. 10 is a configuration diagram showing an example of a schmitt circuit in a semiconductor device according to a prior art.

### DETAILED DESCRIPTION

Hereinafter, a semiconductor device according to an embodiment will be described in detail by referring to the drawings. In the specification and the drawings, the same or corresponding form elements are denoted by the same reference numerals, and a repetitive description thereof is omitted. In the drawings, for convenience of description, the configuration may be omitted or simplified. Also, at least some of the embodiments and each modification may be arbitrarily combined with each other.

### First Embodiment

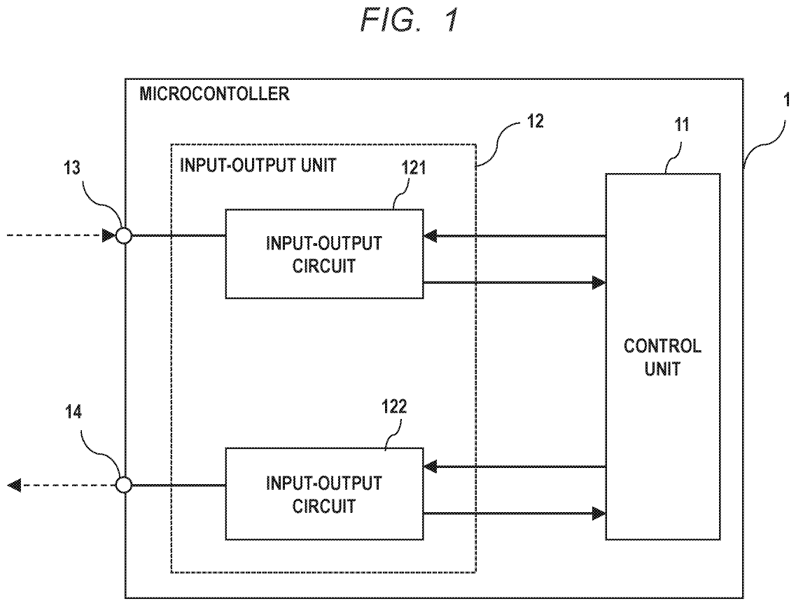

FIG. 1 is a configuration diagram of a semiconductor device according to a first embodiment. In the present embodiment, a microcontroller 1 as the semiconductor device will be described as an example.

The microcontroller 1 has a control unit 11, an input-output unit 12, an input terminal 13 and an output terminal 14. The input terminal 13 and the output terminal 14 are adjacent. The input-output unit 12 has an input-output circuit 121 connected to the input terminal 13 and an input-output circuit 122 connected to the output terminal 14. When an output of the output terminal 14 is toggled, the control unit 11 holds the previous value of an output of the input-output circuit 121 by masking the input of the input-output circuit 121 of the input terminal 13.

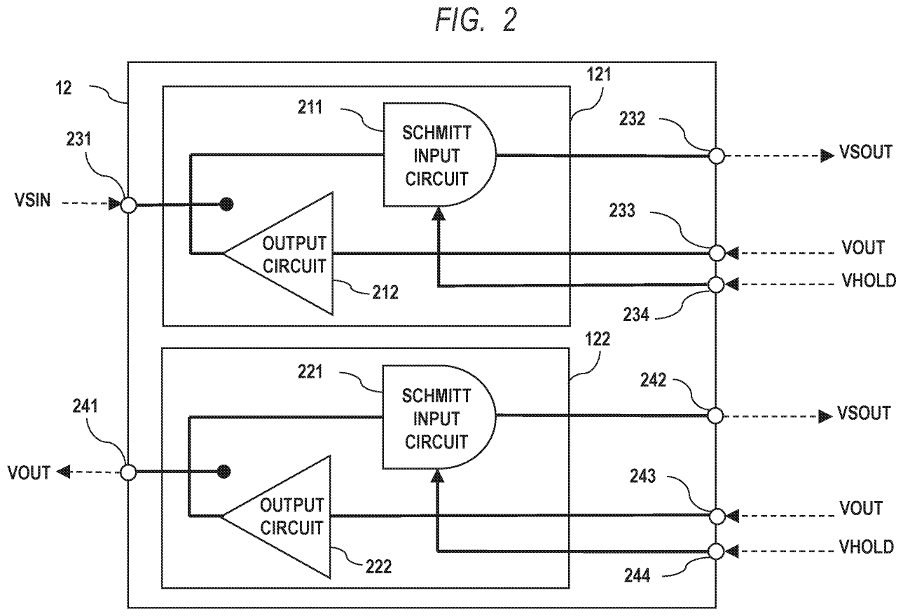

FIG. 2 is a diagram showing a configuration of the input-output unit 12 in the microcontroller 1 of FIG. 1. The input-output circuit 121 includes a schmitt input circuit 211 and an output circuit 212. Similarly, the input-output circuit 122 has a schmitt input circuit 221 and an output circuit 222. Further, the input-output circuits 121 has an input terminal 231, an output terminal 232, an output control signal terminal 233 and a hold signal terminal 234. Similarly, the input-output circuits 122 has an input terminal 241, an output terminal 242, an output control signal terminal 243 and a hold signal terminal 244.

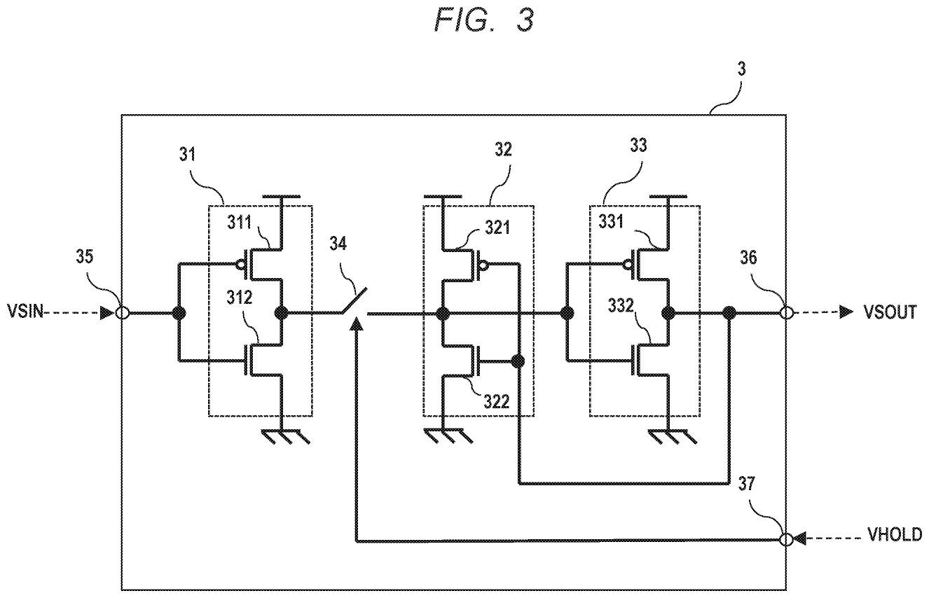

FIG. 3 is a circuit diagram showing an example of the configuration of the schmitt input circuits 211, 221 in FIG. 2. In the first embodiment, a description will be given of a configuration based on an inverter feedback type schmitt input circuit as the schmitt input circuit.

A schmitt input circuit 3 has three stages of inverters 31, 32, 33. The inverter 31 at the first stage has a p-channel MOS transistor 311 and an n-channel MOS transistor 312. Similarly, the inverter 32 at the second stage has a p-channel MOS transistor 321 and an n-channel MOS transistor 322. Similarly, the inverter 33 at the third stage has a p-channel MOS transistor 331 and an n-channel MOS transistor 332.

It also has a switch 34 between the inverter 31 and the inverter 32. Furthermore, it has an input terminal 35 for inputting a schmitt input signal VSIN, an output terminal 36 for outputting a schmitt output signal VSOUT and a hold signal terminal 37 for inputting a hold signal VHOLD to control ON/OFF of the switch 34.

### (Normal Operation)

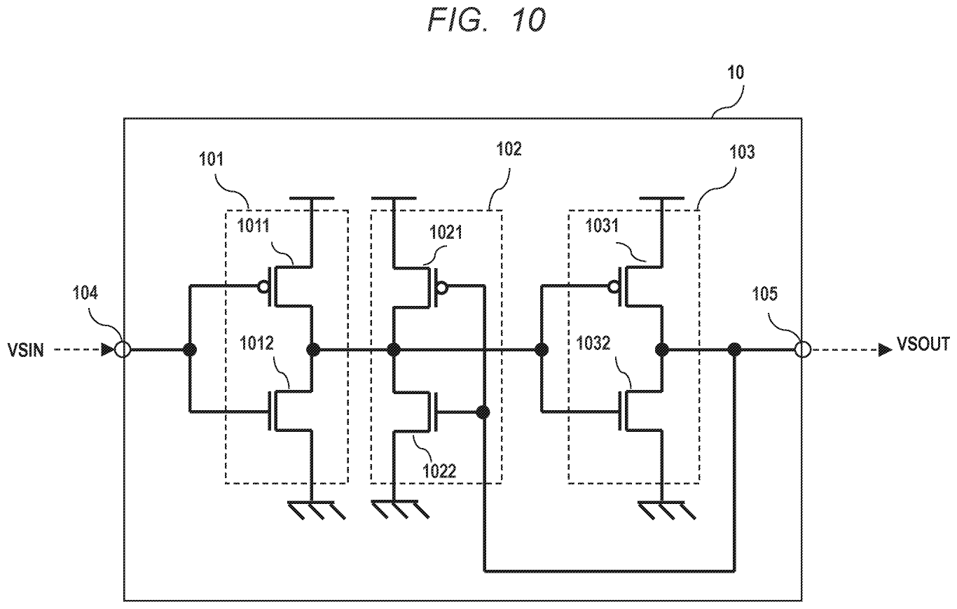

In the schmitt input circuit 3 of FIG. 3, at first, when a noise is not generated, a normal operation of the schmitt input circuit 3 will be described. During the normal operation, the schmitt input circuit 3 is used by short-circuiting the switch 34 by the hold signal VHOLD input from the hold signal terminal 37. That is, the schmitt input circuit 3 has the same operation as the schmitt input circuit 10 of FIG. 10 according to a prior art.

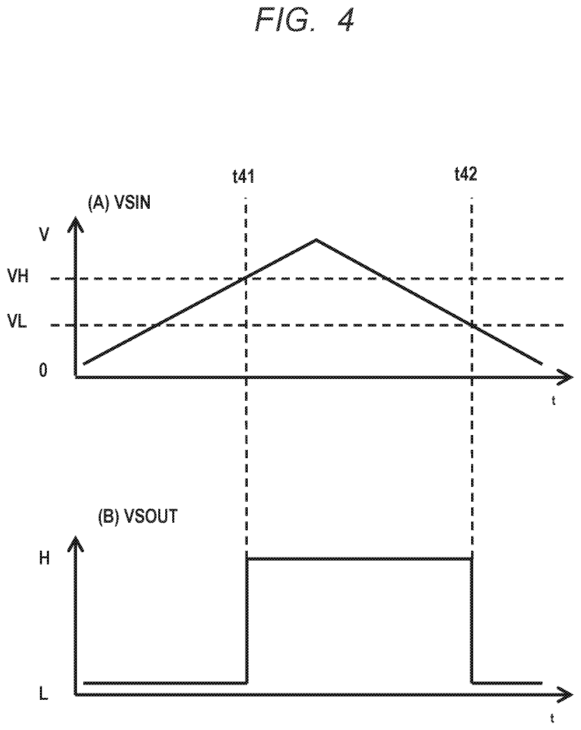

As an example, when the triangular wave is input as the schmitt input signal VSIN from the input terminal 35, FIG. 4 is a diagram showing a waveform of the temporal transitions of the potential of the schmitt input signal VSIN and the schmitt output signal VSOUT.

When the triangle wave of the schmitt input signal VSIN is gradually rising from 0V, if the initial value of the schmitt output signal VSOUT is “Low (L)”, p-channel MOS transistor 321 of the inverter 32 at the second stage is “ON”, the threshold value of the n-channel MOS transistor 312 of the inverter 31 at the first stage is shifted to the current drawn by the p-channel MOS transistor 321. When the potential of the schmitt input signal VSIN reaches the threshold value VH, the schmitt output signal VSOUT is inverted from “Low (L)” to “High(H)” (t41 in FIG. 4).

On the other hand, when the potential of the schmitt input signal VSIN falls, since the schmitt output signal VSOUT is “High (H)”, the n-channel MOS transistor 322 of the inverter 32 is turned “ON”, the threshold value of the p-channel MOS transistor 311 of the inverter 31 is shifted to the current drawn by the n-channel MOS transistor 322. When the potential of the schmitt input signal VSIN reaches the threshold value VL, the schmitt output signal VSOUT is inverted from “High(H)” to “Low(L)” (t42 in FIG. 4).

As described above, during the normal operation, because the threshold value VH in case that the schmitt output signal VSOUT inverts to “High (H)” and the threshold value VH in case that the schmitt output signal VSOUT inverts to “Low(L)” are different, it is possible to have a hysteresis width.

(Operation when the Adjacent Pin Output is Toggled)

Next, when the output of the adjacent output terminal is toggled and noise is generated, the operation of masking the schmitt input will be described. Specifically, a case where the output of the adjacent output terminal 14 is toggled while inputting to the input terminal 13 in FIG. 1 will be described. More specifically, a case where the output of the adjacent output terminal 241 is toggled while inputting to the input terminal 231 in FIG. 2 will be described.

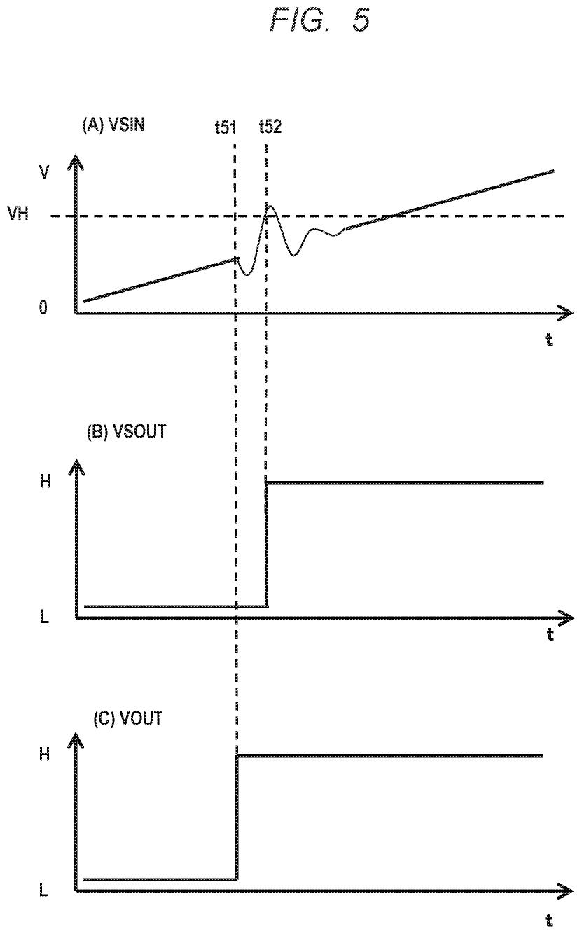

FIG. 5 is a diagram showing a waveform of the temporal transitions of the potential of the schmitt output signal VSOUT outputted from the output terminal 232, when the output control signal VOUT of the output terminal 241 neighboring is inverted from Low (L) to High (H), when the schmitt input signal VSIN input from the input terminal 231 rises from 0V.

The output control signal VOUT of the adjacent output terminal 241 is inverted from “Low (L)” to “High (H)” (t51 in FIG. 5). When the input potential from the input terminal 231 by the input noise caused thereby temporarily exceeds the high-potential-side input threshold value VH, the schmitt output signal VSOUT is inverted at a lower potential than the threshold value VH from the user (t52 in FIG. 5).

(Input Signal Mask Control when the Adjacent Pin Output is Toggled)

The control for reducing the noise influence due to the output toggle of the adjacent output terminal 241 will be described. When the output control signal VOUT of the adjacent output terminals 241 is toggled, the control unit 11 in FIG. 1 performs mask control of the schmitt input signal VSIN by outputting the hold signal VHOLD from the hold signal terminal 234 for a predetermined period.

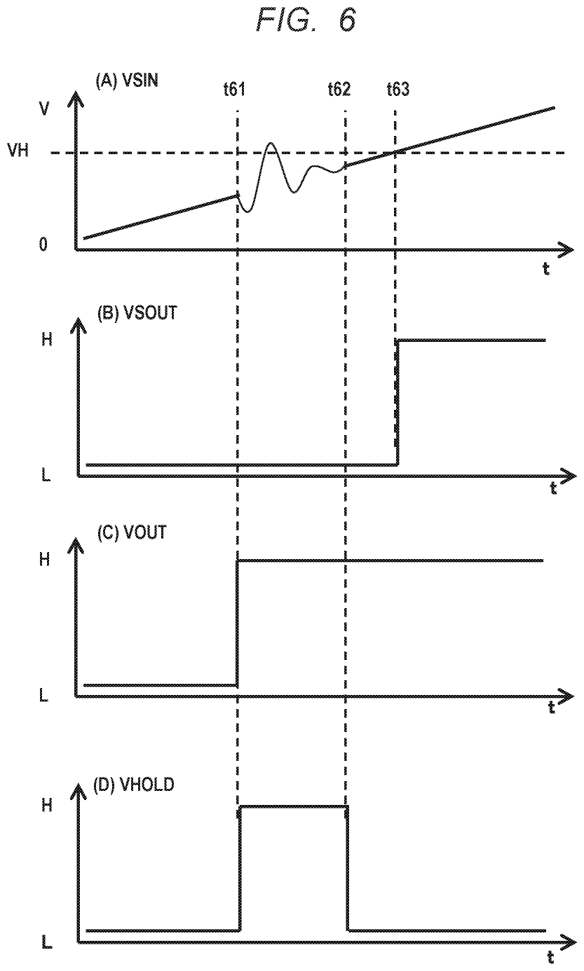

FIG. 6 is a diagram showing a waveform of the temporal transitions of the potential of the schmitt output signal VSOUT and the hold signal VHOLD, when the schmitt input signal VSIN rises from 0V, the output control signal VOUT of the adjacent output terminal 241 is inverted from “Low(L)” to “High(H)”.

The output control signal VOUT of the adjacent output terminal 2431 is a predetermined period from immediately after inverting “Low(L)” to “High(H)” until the noise is stopped (t61˜t62 in FIG. 6), the schmitt input circuit 3 of FIG. 3 by the hold signal VHOLD input from the hold signal terminal 234 to open the switch 34. When the switch 34 is opened, the output potential of the inverter 31 does not propagate to the input of the inverter 33. Further, the potential of the schmitt output signal VSOUT by the inverter 32 is not at an undefined potential because it is applied to the input of the inverter 33, the schmitt output signal VSOUT holds the potential prior to opening the switch 34 (from t61 to t63 in FIG. 6).

When switching the switch 34 to a short circuit by the hold signal VHOLD, the schmitt input circuit 3 returns to normal operation, the schmitt output signal VSOUT is inverted in the original high-potential-side threshold value VH as shown in FIG. 6 (t63 in FIG. 6).

Since the period for masking the schmitt input signal VSIN by the hold signal VHOLD (from t61 to t62 in FIG. 6) depends on the wiring resistance, the parasitic capacitance, the inductance, the driving capacity and the driving load of the output terminal in the microcontroller, an appropriate period must be set for each product. For example, in a typical BGA (Ball Grid Array) package of microcontroller, in case that an output-load capacitance has about 30 pF, the period of masking is assumed to be on the order of several tens of nsec.

In the first embodiment,

(1) When the output of the input-output circuit 122 of the adjacent output terminal 14 side is toggled, because the microcontroller 1 masks the input signal of the input-output circuit 121 at the input terminal 13 side for a predetermined period and holds the previous value of output, it is possible to reduce the noise influence when the output of the adjacent output terminals is toggled.

(2) By providing a switch 34 for shutting off the Schmitt input signal VSIN for a predetermined period in the input circuit 121 and a hold signal terminal 233 for controlling the switch 34, the input noise is prevented from propagating in the subsequent stage of the input circuit 121, it is possible to prevent erroneous determination of the threshold value of the input circuit 121.

### Second Embodiment

In the first embodiment, a configuration example in which the schmitt input circuit is based on the inverter feedback type schmitt input circuit has been described. In the second embodiment, a configuration example based on a latch type schmitt input circuit will be described.

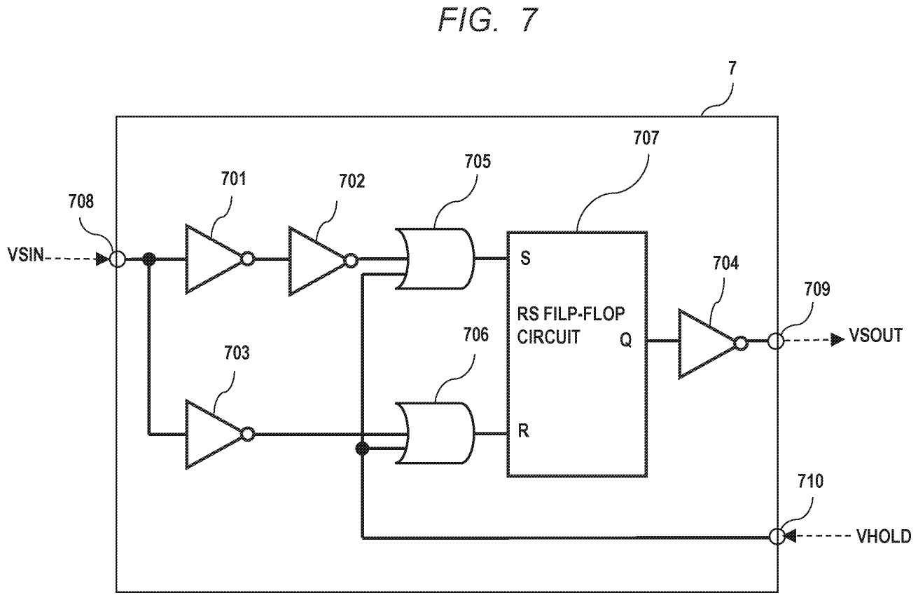

FIG. 7 is a circuit diagram showing an example of a configuration of the schmitt input circuits 211, 221 in FIG. 2. In the second embodiment, as an example of the configuration of a schmitt input circuit 7 based on the latch-type schmitt input circuit will be showed. In this configuration example, as shown in FIG. 7, the schmitt input circuit 7 has inverters 701, 702, 703, 704, logic circuits 705, 706 and RS flip-flop circuit 707.

### (Normal Operation)

It will be described normal operation of the schmitt input circuit 7 in the configuration of the second embodiment.

In FIG. 7, while fixing the hold signal VHOLD to “Low(L)”, the outputs of the logic circuits 705, 706 are the same as the outputs of the inverters 702, 703, respectively, and the schmitt input circuit 7 performs a normal operation. FIG. 4 shows the time-transition waveform of the voltage of the schmitt output signal VSOUT output from the schmitt input signal VSIN and the output terminal 709 input from the input terminal 708. It is the same as the first embodiment.

For the latch type schmitt input circuit 7, the input threshold value VH of the high potential side by the inverter 703 of FIG. 7, respectively determines the input threshold value VL of the low potential side by the inverter 701. Further, it has a hysteresis width by holding the output in the RS flip-flop circuit 707.

FIG. 4 will be described when gradually rising from the potential 0V of the schmitt input signal VSIN input from the input terminal 708.

Since the first input potential of the schmitt input signal VSIN is 0V, the input S of the RS flip-flop circuit 707 is “Low (L)”, the input R is “High(H)”, the output Q becomes “High(H)”, the schmitt output signal VSOUT output from the output terminal 709 becomes “Low(L)”. Further when the input potential of the schmitt input signal VSIN is increased, the output of the inverter 701 is inverted to “Low(L)”, the input S and the input R are both “High(H)”, since a previous value of the output Q, “High(H)” is held, the schmitt output signal VSOUT is also held “Low(L)”. Further if the input potential of the schmitt input signal VSIN exceeds the threshold value VH of the inverter 703 rises, the output of the inverter 703 is inverted from “High (H)” to “Low(L)”, the input S of the RS flip-flop circuit 707 is “High(H)”, the input R is “Low(L)”, the output Q becomes “Low (L)”, the schmitt output signal VSOUT is inverted to “High(H)” (t41 in FIG. 4).

Next, a description will be given of a case where the potential of the schmitt input-signal VSIN falls gradually from the power supply voltage. When the schmitt input signal VSIN is the power supply voltage, the input S of the RS flip-flop circuit 707 “High (H)”, since the input R is “Low (L)”, the output Q of the RS flip-flop circuit 707 becomes “Low (L)”, the schmitt output signal VSOUT becomes “High(H)”.

When the potential of the schmitt input signal VSIN is gradually decreased, the output of the inverter 703 is inverted from “Low(L)” to “High(H)”, the input S of the RS flip-flop circuit 707 is “High(H)”, the input R is “High(H)”, the output Q is a previous value “Low (L)” is held, the schmitt output signal VSOUT “High(H)” is also held.

Furthermore, when the potential of the schmitt input signal VSIN is lower than the threshold value VL of the inverter 701, the output of the inverter 701 is inverted from “Low (L)” to “High (H)”, the input S of the RS flip-flop circuit 707 is “Low(L)”, the input R becomes “High (H)”, the output Q is inverted to “High (H)”, the schmitt output signal VSOUT is also inverted to “Low (L)” (t42 in FIG. 4).

(Input Signal Mask Control when the Adjacent Pin Output is Toggled)

The control for reducing the noise influence due to the output toggle of the adjacent output terminal 241 will be described. The control unit 11 in FIG. 1, when the output control signal VOUT of the adjacent output terminal 241 is toggled, performs mask control of the input signal by outputting a hold signal VHOLD from the hold signal terminal 234 for a predetermined period. A waveform in the mask control is similar to FIG. 6 in the first embodiment.

The output control signal VOUT of the adjacent output terminal 241 is a predetermined period from immediately after inverted from Low (L) to High(H) until the noise is stopped (from t61 to t62 in FIG. 6), the hold signal VHOLD from the hold signal terminal 234 to “High (H)”. When the hold signal VHOLD becomes “High(H)”, the output of the logic circuits 705, 706 in the schmitt input circuit 211 of FIG. 7 is fixed to “High(H)” regardless of the output of the inverters 701, 702.

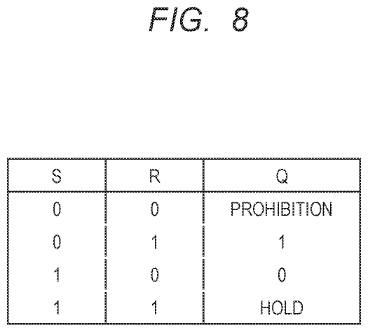

Therefore, since the input S and the input R of the RS flip-flop circuit 707 are also fixed to “High(H)”, the output Q of the RS flip-flop circuit 707 is retained as shown in the truth table of the RS flip-flop circuit of FIG. 8. Thus, the schmitt output signal VSOUT is also the previous value is held.

After switching the hold signal VHOLD to “Low (L)”, since the outputs of the logic circuits 705, 706 are the same as the outputs of the inverters 701, 702, respectively, the schmitt input circuit 211 returns to normal operation. As shown in FIG. 6, at the original high-potential-side threshold value VH, the schmitt output signal VSOUT is inverted from “Low(L)” to “High (H)” (t63 in FIG. 6).

In the second embodiment, not only the inverter feedback type schmitt circuit in the first embodiment, the output of the schmitt input circuit by masking the schmitt input signal for a predetermined period even in the latch type schmitt circuit hold the previous value, it is possible to reduce the noise influence at the time of output toggle of the adjacent output terminals.

### Third Embodiment

As a schmitt input circuit, the configuration based on the inverter feedback type schmitt input circuit is described in the first embodiment. Similarly, the configuration based on the latch type schmitt input circuit is described in the second embodiment. In contrast, in the third embodiment, a configuration based on the conventional schmitt input circuit will be described.

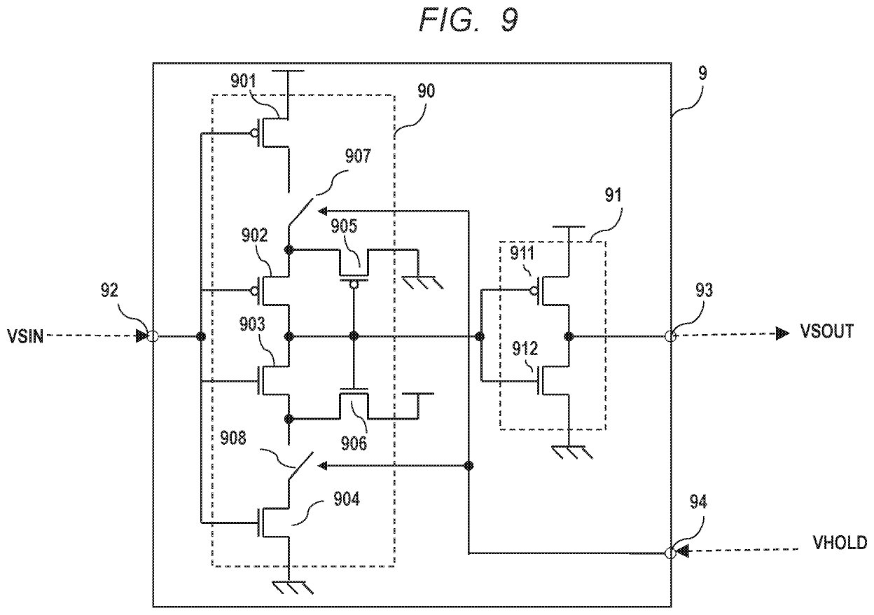

FIG. 9 is a circuit diagram showing an example of the configuration of the schmitt input circuit 211, 221 in FIG. 2. The second embodiment shows an example of a configuration of a schmitt input circuit 9 based on the conventional schmitt input circuit. This configuration example includes p-channel MOS transistors 901, 902, 905 and n-channel MOS transistors 903, 904, 906 that compose the first stage inverter 90 as shown in FIG. 9. It also has a p-channel MOS transistor 911 and the n-channel MOS transistor 912 constituting the inverter 91 of the subsequent stage. It also has switches 907, 908 controlled ON/OFF by a hold signal VHOLD.

### (Normal Operation)

It will be described normal operation of the schmitt input circuit 9 in the configuration of the third embodiment.

While short-circuiting the switches 907, 908 by the hold signal VHOLD in FIG. 9, it operates as a normal schmitt input circuit. The time-transition waveform of the voltage of the schmitt input signal VSIN and the schmitt output signal VSOUT when the normal operation, as shown in FIG. 4 is the same as the first embodiment and the second embodiment.

FIG. 4 will be described when gradually rising from the potential 0V of the schmitt input signal VSIN. Since the first input potential of the schmitt input signal VSIN is 0V, the p-channel MOS transistors 901, 902 are turned “ON”, the n-channel MOS transistor 912 of the subsequent inverter 91 is also turned “ON”, the schmitt output signal VSOUT is “Low(L)”.

Even if the input voltage of the schmitt input signal VSIN begins to increase gradually, the threshold value of the n-channel MOS transistor 904 is shifted to the high potential by the current drawn by the n-channel MOS transistor 906. When the input potential of the schmitt input signal VSIN is further raised, the n-channel MOS transistors 903, 904 are turned ON, the p-channel MOS transistor 911 of the subsequent inverter 91 is also turned ON, the schmitt output signal VSOUT is inverted to “High(H)” (t41 in FIG. 4). The threshold value VH when the schmitt output signal VSOUT is inverted to “High(H)” is determined by the n-channel MOS transistors 904, 906.

Next, a description will be given of a case where the input potential of the schmitt input signal VSIN falls from the power supply voltage to 0V. Since the initial input potential of the schmitt input signal VSIN is the power supply voltage, the n-channel MOS transistors 903 and 904 are turned ON, the p-channel MOS transistor 911 of the subsequent inverter 91 is also turned ON, the schmitt output signal VSOUT “High(H)” is output.

Even if the input voltage of the schmitt input signal VSIN begins to gradually decrease, the threshold value of the p-channel MOS transistor 901 is shifted to the lower potential by the current drawn by the p-channel MOS transistor 905. When the input potential of the schmitt input signal VSIN is further reduced, the p-channel MOS transistors 901, 902 are turned “ON”, the n-channel MOS transistor 912 of the subsequent inverter 91 is also turned “ON”, the schmitt output signal VSOUT is inverted to “Low(L)” (t42 in FIG. 4). The threshold value VL that schmitt output signal VSOUT is inverted to “Low(L)” is determined by the p-channel MOS transistors 901, 905.

(Input Signal Mask Control when the Adjacent Pin Output is Toggled)

The control for reducing the noise influence due to the output toggle of the adjacent output terminal 241 will be described. When the output control signal VOUT of the output terminal 241 neighboring is toggled, the control unit 11 in FIG. 1, performs mask control of the input signal by outputting a hold signal VHOLD from the hold signal terminal 234 for a predetermined period. The waveform in the mask control is similar to the first embodiment and the second embodiment, as shown in FIG. 6.

By FIG. 6, the output control signal VOUT of the output terminal 241 which is adjacent when the input potential of the schmitt input signal VSIN is equal to or less than the threshold value VH is inverted from “Low (L)” to “High (H)” will be described. The switches 907 and 908 in FIG. 9 are opened by the hold signal VHOLD for a predetermined period (from t61 to t62 in FIG. 6) from immediately after the output control signal VOUT is inverted until the noise is stopped. Just before the switches 907, 908 are opened, the gate potential of the p-channel MOS transistor 905 and the n-channel MOS transistor 906 becomes the power supply voltage because the p-channel MOS transistors 901, 902 are “ON”. Even when the switches 907, 908 are open, by the parasitic capacitances of the p-channel MOS transistors 902, 905 and the n-channel MOS transistors 903, 906, the gate potential of the p-channel MOS transistor 905 and the n-channel MOS transistor 906 is held at the power supply voltage. Thus, the output of the subsequent inverter 91 is also held “Low(L)”.

After a predetermined time until the noise is reduced, after switching the switches 907, 908 to a short circuit by the hold signal VHOLD, schmitt input circuit 9 returns to normal operation, schmitt output signal VSOUT in the original high-potential-side threshold value VH is inverted as shown in FIG. 6.

In the third embodiment, because not only the inverter feedback type schmitt circuit in the first embodiment and the latch type schmitt circuit in the second embodiment but also the conventional type schmitt circuit masks the schmitt input signal for a predetermined period and holds the previous value of the output of schmitt circuit, it is possible to reduce the noise influence at the time of the adjacent terminal output toggle.

It should be noted that the present invention is not limited to the above-mentioned embodiments, and various modifications can be made without departing from the gist thereof.

What is claimed is:

1. A semiconductor device comprising:
a first input terminal for inputting a first signal,
a first output terminal for outputting a second signal,
an input-output unit connected to the first input terminal and the second terminal for processing the first signal and the second signal, and
a control unit for sending a third signal to the input-output unit to control based on the second signal.

2. The semiconductor device according to claim 1,
wherein the input-output unit has an input-output circuit for inputting the first signal, and for controlling the first signal based on the third signal.

3. The semiconductor device according to claim 2,
wherein the control unit transmits the third signal to the input-output circuit when detecting that the second signal is toggled.

4. The semiconductor device according to claim 3,
wherein the input-output circuit is an inverter feedback type schmitt input circuit, having a first inverter, a second inverter, a third inverter, and a first switch between the first inverter and the second inverter,
wherein the first switch is turned on while receiving the third signal.

5. The semiconductor device according to claim 3,
wherein the input-output circuit is a latch type schmitt input circuit, having a plurality of inverters, a first logic circuit, a second logic circuit, and an RS flip-flop circuit,
wherein the first logic circuit is connected to the input S of the RS flip-flop circuit, and the second logic circuit is connected to the input R of the RS flip-flop circuit,
wherein the input S and the input R are fixed to a high while receiving the third signal, and the output Q of the RS flip-flop circuit retains a previous value.

6. The semiconductor device according to claim 3,
wherein the input-output circuit is a conventional type schmitt input circuit, having a fourth inverter with a second switch and a third switch, and a fifth inverter,
wherein the second switch and the third switch are turned on while receiving the third signal.

7. The semiconductor device according to claim 3,
Wherein a period during which the third signal is output is set from the outside.

8. An input signal controlling method for a semiconductor device, the semiconductor device comprising
a first input terminal for inputting a first signal,
a second input terminal for inputting a second signal,
an input-output unit connected to the first input terminal and the second terminal for processing the first signal and the second signal, and
a control unit for sending a third signal to the input-output unit to control based on the second signal,
wherein the control unit transmits the third signal to the input-output circuit when detecting that the second signal is toggled.

9. The input signal controlling method according to claim 8,
wherein the input-output unit has an input-output circuit for inputting the first signal, and for controlling the first signal based on the third signal,
wherein the control unit transmits the third signal to the input-output circuit when detecting that the second signal is toggled.

10. The input signal controlling method according to claim 9,
wherein the input-output circuit is either a latch type schmitt input circuit or a conventional type schmitt input circuit or a conventional type schmitt input circuit.
